(19) United States
(12) Patent Application Publication
(10) Pub. No.: US 2025/0310657 A1
(43) Pub. Date: Oct. 2, 2025

(54) PHOTOELECTRIC CONVERSION APPARATUS AND PHOTOELECTRIC CONVERSION SYSTEM

(71) Applicant: CANON KABUSHIKI KAISHA, Tokyo (JP)

(72) Inventor: TOMOYA SASAGO, Kanagawa (JP)

(21) Appl. No.: 19/088,713

(22) Filed: Mar. 24, 2025

(30) Foreign Application Priority Data
Mar. 26, 2024 (JP) 2024-050583

(51) Int. Cl. H04N 25/47; H04N 25/773; H04N 25/779

(52) U.S. Cl. CPC H04N 25/47; H04N 25/773; H04N 25/779

(57) ABSTRACT

A photoelectric conversion apparatus includes a drive line through which signals input into signal processing circuits are transmitted. The driving line is branched into a first driving line and a second driving line via a buffer circuit. A signal from the first driving line is capable of being input into the signal processing circuit of a first pixel on a first line. A signal from the second driving line is capable of being input into the signal processing circuit of a second pixel on a second line.

### BACKGROUND

### Technical Field

The present disclosure relates to a photoelectric conversion apparatus and a photoelectric conversion system.

### Description of the Related Art

A known photodetector uses an avalanche photodiode (APD) capable of detecting weak light in a single photon level using avalanche multiplication. In the APD, a first-conductivity-type first semiconductor region having the same polarity as that of a signal charge and a second-conductivity-type second semiconductor region having a polarity different from that of the signal charge form an avalanche multiplication portion, which is a high electric-field region.

Japanese Patent Laid-Open No. 2020-123847 describes a photoelectric conversion apparatus that includes a switch between the APD and a power source and that controls turning-on and turning-off of the switch with a clock signal. In addition, provision of a driving line PVSEL for each line of a pixel array and supply of the clock signal to each pixel through the driving line PVSEL are described in Japanese Patent Laid-Open No. 2020-123847.

A specific configuration of the driving line PVSEL is not described in detail in Japanese Patent Laid-Open No. 2020-123847.

### SUMMARY

Accordingly, embodiments of the present disclosure provide a photoelectric conversion apparatus capable of acquiring highly reliable data by further devising the driving line PVSEL in Japanese Patent Laid-Open No. 2020-123847.

Embodiments of the present disclosure provide a photoelectric conversion apparatus including multiple pixels arranged in a matrix. Each of the multiple pixels includes at least a photodiode configured to perform avalanche multiplication and a signal processing circuit configured to process an output signal from the photodiode. The signal processing circuit includes a charge circuit arranged between the photodiode and a power supply and configured to apply voltage to the photodiode, and a counter circuit configured to count the output signal from the photodiode. The photoelectric conversion apparatus further includes a driving line through which a signal to be input into the signal processing circuit is transmitted. The driving line is branched into at least a first driving line and a second driving line via a buffer circuit. A signal from the first driving line is capable of being input into the signal processing circuit of a first pixel, of the plurality of pixels, on a first line. A signal from the second driving line is capable of being input into the signal processing circuit of a second pixel, of the plurality of pixels, on a second line different from the first line.

Further features of various embodiments will become apparent from the following description of exemplary embodiments with reference to the attached drawings.

### BRIEF DESCRIPTION OF THE DRAWINGS

FIG. 1 illustrates a configuration of a photoelectric conversion apparatus according to a first embodiment.

FIG. 2 illustrates an example of arrangement on a sensor substrate.

FIG. 3 illustrates an example of arrangement on a circuit board.

FIG. 4 is a block diagram including an equivalent circuit of a photoelectric conversion element.

FIG. 5A illustrates the relationship between an operation of an APD and output signals, and FIG. 5B is a graph indicating the relationship between illuminance and a count value.

FIG. 6A and FIG. 6B illustrate the relationship between driving lines and pixels of the first embodiment.

FIG. 7 illustrates a pixel circuit of a second embodiment.

FIG. 8 is a timing chart concerning driving of the pixel circuit of the second embodiment.

FIG. 9 illustrates the relationship between driving lines and pixels of the second embodiment.

FIG. 10A illustrates a specific configuration of a buffer circuit, and FIG. 10B illustrates the relationship between driving lines and pixels of a third embodiment.

FIG. 11 is a block diagram of a photoelectric conversion system of a fourth embodiment.

FIG. 12A and FIG. 12B are block diagrams of a photoelectric conversion system of a fifth embodiment.

FIG. 13 is a block diagram of a photoelectric conversion system of a sixth embodiment.

FIG. 14 is a block diagram of a photoelectric conversion system of a seventh embodiment.

FIG. 15A and FIG. 15B are diagrams illustrating specific examples of a photoelectric conversion system of an eighth embodiment.

### DESCRIPTION OF THE EMBODIMENTS

The embodiments described below embody the technical ideas of the present disclosure and do not limit every embodiment of the present disclosure. The sizes and the positional relationships of members illustrated in the respective drawings may be exaggerated in order to clarify the description. The same reference numerals are used in the following description to identify the same components and a description of such components may be omitted. Components described in each embodiment may be replaced or combined with components described in another embodiment as long as no technical problem occurs.

Example embodiments of the present disclosure will herein be described in detail with reference to the drawings. Terms indicating specific directions and positions (for example, “top”, “bottom”, “right”, “left”, and other terms including theses terms) are used in the following description, if needed. These terms are used to facilitate understanding of the present disclosure with reference to the drawings, and the technical scope of the present disclosure is not limited by the meanings of these terms.

Connection between elements in a circuit may be described in the following description. In this case, even if another element exists between target elements, the target elements are considered as being connected unless otherwise specified.

In the following description, the anode of an avalanche photodiode (APD) is set to fixed electric potential and a signal is extracted from the cathode side. Accordingly, a first-conductivity-type semiconductor region having an electric charge of the same polarity as that of a signal charge as majority carrier is an N-type semiconductor region, and a second-conductivity-type semiconductor region having an electric charge of a polarity different from that of the signal charge as majority carrier is a P-type semiconductor region. The cathode of the APD may be set to the fixed electric potential, and a signal may be extracted from the anode side. In this case, the first-conductivity-type semiconductor region having an electric charge of the same polarity as that of the signal charge as majority carrier is the P-type semiconductor region, and the second-conductivity-type semiconductor region having an electric charge of a polarity different from that of the signal charge as majority carrier is the N-type semiconductor region. Although the case in which one node of the APD is set to the fixed electric potential is described below, the electric potentials of both nodes of the APD may be varied.

### First Embodiment

### Overall Configuration

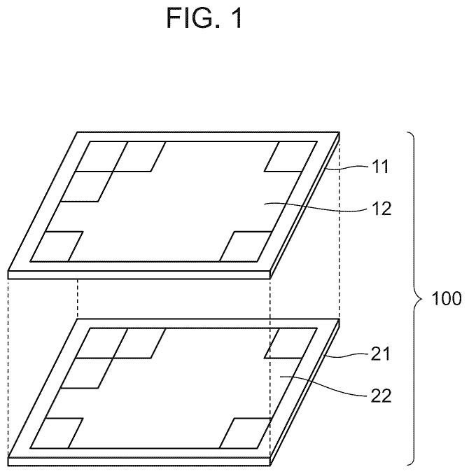

FIG. 1 illustrates a configuration of a lamination-type photoelectric conversion apparatus 100 according to a first embodiment. The photoelectric conversion apparatus 100 is composed of a sensor substrate 11 and a circuit board 21 that are laminated to be electrically connected to each other. The sensor substrate 11 has a first semiconductor layer having photoelectric conversion elements 102 and a first wiring structure. The circuit board 21 has a second semiconductor layer having circuits, such as signal processors 103, and a second wiring structure. The photoelectric conversion apparatus 100 is composed of the second semiconductor layer, the second wiring structure, the first wiring structure, and the first semiconductor layer, which are sequentially laminated. The photoelectric conversion apparatus described in each embodiment is a back-illuminated photoelectric conversion apparatus in which light is incident from a second face and the circuit board is arranged on a first face.

Although the sensor substrate 11 and the circuit board 21 are described as chips that are diced in the following description, the sensor substrate 11 and the circuit board 21 are not limited to the chips. For example, each of the sensor substrate 11 and the circuit board 21 may be a wafer. In addition, each of the sensor substrate 11 and the circuit board 21 may be diced after being laminated in a wafer state. Also, each of the sensor substrate 11 and the circuit board 21 may be chipped from the wafer state and, then, the respective chips may be laminated for bonding.

A photoelectric conversion area 12 is arranged on the sensor substrate 11, and a circuit area 22 in which a signal detected in the photoelectric conversion area 12 is processed is arranged on the circuit board 21.

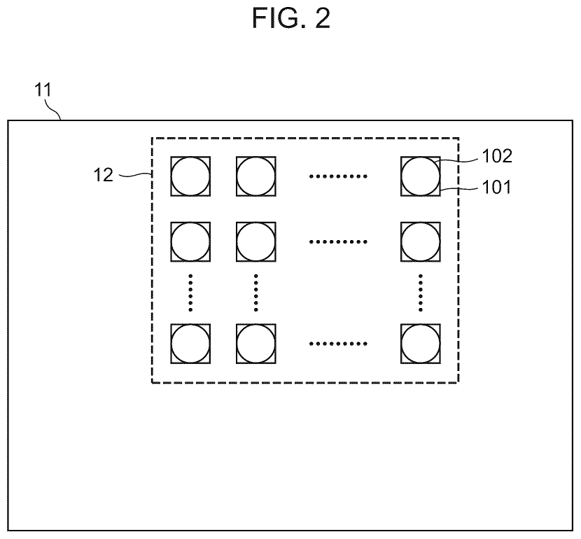

FIG. 2 illustrates an example of arrangement on the sensor substrate 11. Pixels 101 each having the photoelectric conversion element 102 including the APD are aligned in a two-dimensional array in a plan view to form the photoelectric conversion area 12.

Here, the plan view means viewing the sensor substrate 11 from a direction perpendicular to the main faces of the semiconductor layers.

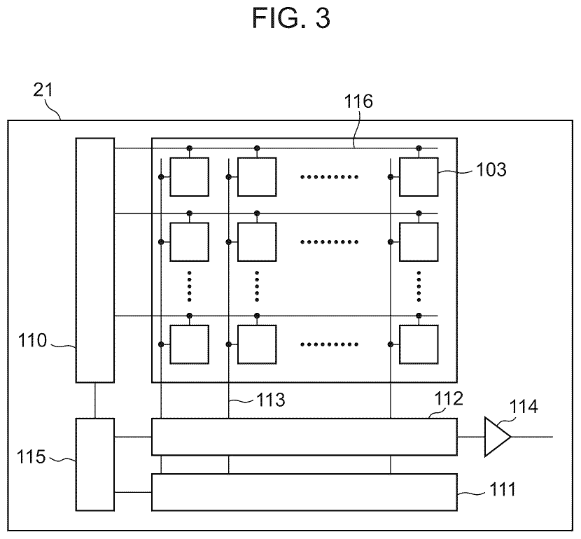

FIG. 3 illustrates a configuration of the circuit board 21. The circuit board 21 has the signal processors 103 that process electric charges subjected to photoelectric conversion in the photoelectric conversion elements 102 in FIG. 2, a readout circuit 112, a control pulse generator 115, a horizontal scanning circuit unit 111, signal lines 113, and a vertical scanning circuit unit 110.

In this specification, one unit including the photoelectric conversion element 102 and the signal processor 103 may be considered as a pixel. In other words, the unit of the element provided on the sensor substrate 11 is not represented as a pixel, but a complex of the element provided on the sensor substrate 11 and the element provided on the circuit board 21 is represented as a pixel. In this case, the photoelectric conversion apparatus is capable of being represented as an apparatus in which the multiple pixels are aligned in a matrix of N-number lines and M-number columns (N is an integer not less than two and M is an integer not less than two) and each pixel at least includes the APD and a signal processing circuit that processes an output signal from the APD.

The photoelectric conversion elements 102 in FIG. 2 are electrically connected to the signal processors 103 in FIG. 3 via connection wiring provided for each pixel.

The vertical scanning circuit unit 110 receives a control pulse supplied from the control pulse generator 115 and supplies the control pulse to each pixel. Specifically, driving lines 116 extend in the line direction and the control pulse is supplied to the signal processors 103 through the respective driving lines 116. The driving lines 116 will be described in detail below. Logic circuits including a shift register and an address decoder are used for the vertical scanning circuit unit 110.

A signal output from the photoelectric conversion element 102 of the pixel is processed in the signal processor 103. A counter, a memory, and so on are provided in the signal processor 103. A digital value is written into the memory to store information.

The horizontal scanning circuit unit 111 supplies the control pulses sequentially selecting the respective columns to the signal processors 103 in order to read out a signal from the memory of each pixel, in which a digital signal is held.

Signals are output from the signal processors 103 of the pixels selected by the vertical scanning circuit unit 110 to the signal line 113 for the selected column.

The signals output to the signal lines 113 are output to the outside of the photoelectric conversion apparatus 100 through an output circuit 114.

As illustrated in FIG. 2 and FIG. 3, the multiple signal processors 103 are arranged in an area overlapped with the photoelectric conversion area 12 in a plan view. The vertical scanning circuit unit 110, the horizontal scanning circuit unit 111, the readout circuit 112, the output circuit 114, and the control pulse generator 115 are arranged so as to be overlapped with a portion between ends of the sensor substrate 11 and ends of the photoelectric conversion area 12 in a plan view. In other words, the sensor substrate 11 has the photoelectric conversion area 12 and a non-photoelectric conversion area arranged around the photoelectric conversion area 12. The vertical scanning circuit unit 110, the horizontal scanning circuit unit 111, the readout circuit 112, the output circuit 114, and the control pulse generator 115 are arranged in an area overlapped with the non-photoelectric conversion area in a plan view.

### Pixel Circuit

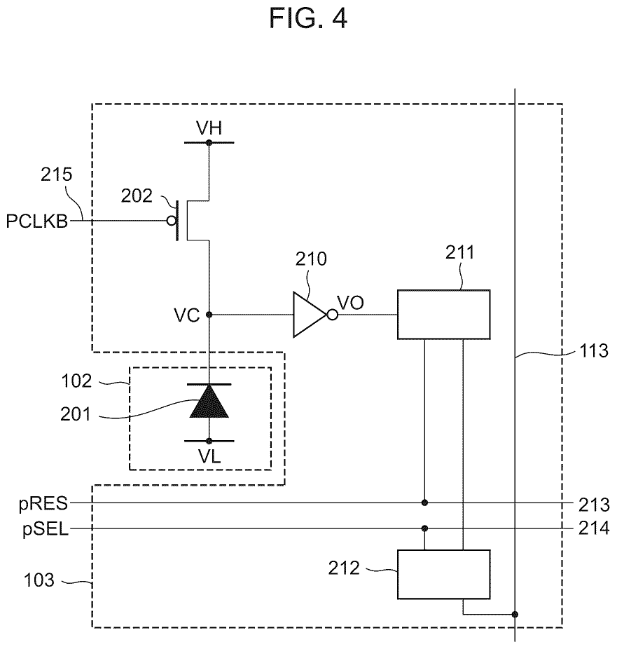

FIG. 4 illustrates an equivalent circuit and a block diagram of the photoelectric conversion element including the APD. Referring to FIG. 4, the photoelectric conversion element 102 including an APD 201 is provided on the sensor substrate 11 and the other elements are provided on the circuit board 21.

The APD 201 generates a charge pair corresponding to incident light through the photoelectric conversion. Voltage VL (first voltage) is supplied to the anode of the APD 201. Voltage VH (second voltage) higher than the voltage VL supplied to the anode is supplied to the cathode of the APD 201. Reverse bias voltage causing the APD 201 to perform an avalanche multiplication operation is supplied to the anode and the cathode. In a state in which such voltages are supplied, the electric charge caused by the incident light causes avalanche multiplication to generate an avalanche current.

There is a Geiger mode and a linear mode in the case in which the reverse bias voltage is supplied. In the Geiger mode, the APD 201 is operated in a difference in potential between the anode and the cathode, which is greater than the breakdown voltage. In the linear mode, the APD 201 is operated in a difference in potential between the anode and the cathode, which is near the breakdown voltage or smaller than the breakdown voltage.

The APD operated in the Geiger mode is called a single photon avalanche diode (SPAD). For example, the voltage VL (the first voltage) is set to −30 V and the voltage VH (the second voltage) is set to 3 V. Also, for example, the voltage VL (the first voltage) may be set to 0 V and the voltage VH (the second voltage) may be set to 33 V. The APD 201 may be operated in the linear mode or in the Geiger mode.

A charge circuit 202 is connected to a power supply that supplies the voltage VH and to the APD 201. For example, the charge circuit 202 may be a p-channel metal oxide semiconductor (PMOS) transistor. The charge circuit 202 works so as to return the voltage to be supplied to the APD 201 to the voltage VH in an on state (a charge operation or a recharge operation). Specifically, since the transistor is in the on state when a signal PCLKB to be input into the gate of the PMOS transistor is in an L level, the APD 201 is in a charge state. In contrast, since the transistor is in an off state after recharge when the signal PCLKB to be input into the gate of the PMOS transistor is in an H level, the APD 201 is in a standby state in which the avalanche multiplication is available. In other words, the circuit (the transistor) is arranged between the APD 201 and the power supply (the voltage VH) and the circuit performs control to switch between a first state in which the APD 201 is electrically connected to the power supply and a second state in which the APD 201 is not electrically connected to the power supply. In this case, the first state is the charge state (a recharge state) and the second state is the standby state.

The signal processor 103 includes a waveform shaper 210, a counter circuit 211, and a selection circuit 212.

The waveform shaper 210 shapes a variation in the potential of the cathode of the APD 201, which occurs in detection of a photon, to output a pulse signal. For example, an inverter circuit may be used as the waveform shaper 210. Although the example in which one inverter is used as the waveform shaper 210 is illustrated in FIG. 4, a circuit in which multiple inverters are connected in series may be used or another circuit having the waveform shaping effect may be used.

The counter circuit 211 counts the number (the number of times) of the pulse signals output from the waveform shaper 210 and holds a count value. When a signal pRES is supplied through a driving line 213, the count value held in the counter circuit 211 is reset. In this specification, not only a signal caused by a variation in the voltage at a cathode terminal VC but also the signal output from the waveform shaper 210 may be referred to as an output signal from the APD 201.

The selection circuit 212 receives a signal pSEL from the vertical scanning circuit unit 110 in FIG. 3 via a driving line 214 in FIG. 4 to switch between electrical connection and electrical disconnection between the counter circuit 211 and the signal line 113. The selection circuit 212 includes, for example, a buffer circuit for outputting a signal.

### Clock Recharge Operation

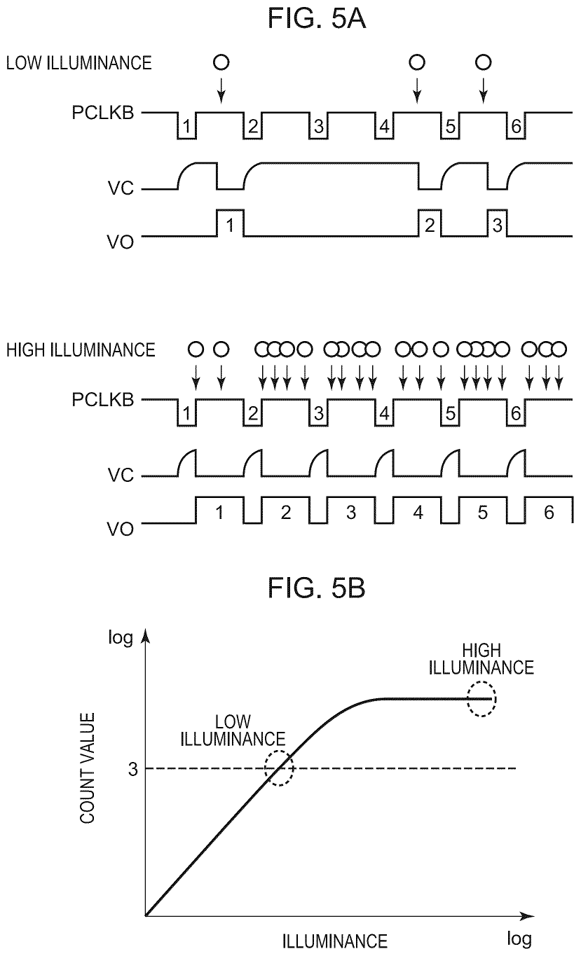

FIG. 5A illustrates a clock recharge operation, which is an operation of the pixel circuit illustrated in FIG. 4. The signal PCLKB, the voltage at the cathode terminal VC, and a signal at VO are indicated in FIG. 5A.

In case of low illuminance, upon incidence of the photon in the H level (the standby state) of the signal PCLKB, the voltage at the cathode terminal VC is decreased to the L level. As a result, the signal at VO, which is the output from the inverter circuit, the waveform shaper 210, is varied from the L level to the H level. Then, when the signal PCLKB is in the L level, the pixel circuit is in the recharge state and the voltage at the cathode terminal VC is varied from the L level to the H level. As a result, the signal at VO, which is the output from the inverter circuit, the waveform shaper 210, is varied from the H level to the L level to generate one signal.

In contrast, in case of high illuminance, even if the incidence of the photon frequently occurs when the signal PCLKB is in the H level (the standby state), the voltage at the cathode terminal VC is kept at the L level as long as the signal PCLKB is in the H level. As a result, the signal at VO in the H level is kept at the H level.

Then, since the voltage at the cathode terminal VC is varied from the L level to the H level in response to the variation from the H level to the L level of the signal PCLKB, the output from VO is varied from the H level to the L level to generate one signal.

In other words, in a clock charge circuit, at least one count is made because at least one signal is generated even in the high illuminance in which the multiple photons are incident in the standby state. FIG. 5B is a graph indicating the relationship between the illuminance and the count value in the clock charge circuit. In the relationship indicated in FIG. 5B, the count value in the low illuminance is not made higher than the count value in the high illuminance even in the high illuminance status.

A passive recharge circuit including a resistive element is also supposed as the charge circuit 202. In the case of the passive recharge circuit, since the photon is incident again before the voltage at the cathode terminal VC is varied from the L level to the H level in the high illuminance, the voltage at the cathode terminal VC is kept at the L level and the signal at VO is kept at the H level. In such a status, the falling of the signal at VO is not detected and no signal is counted. In other words, a case disadvantageously occurs in which no signal is generated regardless of the high illuminance. As a result, a status may occur in which the count value in the high illuminance is made lower than the count value in the low illuminance. In contrast, as described above, the clock charge circuit has the advantage that the count value in the low illuminance is not made higher than the count value in the high illuminance although the upper limit of the count value is determined depending on the number of clock signals. As a result, the clock charge circuit is capable of making an appropriate count value in the high illuminance, compared with the passive recharge circuit, to broaden a dynamic range.

In the clock charge circuit, the pulse signal output from the vertical scanning circuit unit 110 is supplied to the charge circuit 202, for example, through the driving line extending in the line direction as the signal PCLKB. Since parasitic capacitance or parasitic resistance is added to the driving line through which the pulse signal is transmitted, the rising time and the falling time of the waveform of the pulse signal are possibly lengthened to narrow the width of the pulse signal. If the pulse width of the signal PCLKB is narrowed, the charge circuit 202 may have insufficient time to recharge the cathode terminal VC. If the charge circuit 202 has the insufficient recharge time, a state occurs in which the reverse bias voltage that may cause the avalanche multiplication is not applied. As a result, it is not possible to detect the photon even if the signal PCLKB is input, which may possibly cause the counting of the photons to be missed.

In order to resolve the above problem, transmission of the signal through the buffer circuit is considered in order to improve the reliability of the pulse signal corresponding to the signal PCLKB. The buffer circuit is composed of, for example, a one-stage inverter or a multistage inverter.

### Relationship Between Signal Processors and Driving Lines

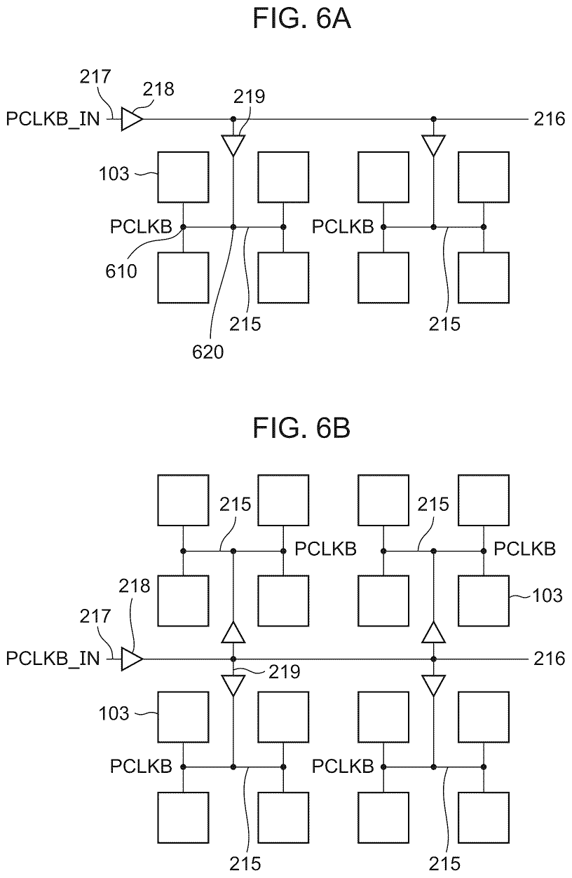

FIG. 6A is a diagram illustrating the relationship between driving lines input into the pixel circuit illustrated in FIG. 4. Specifically, the relationship between the signal processors 103, driving lines 215 and 216, and buffer circuits 218 and 219 is illustrated in FIG. 6A. A signal PCLKB_IN is a pulse signal output from the vertical scanning circuit unit 110 and is transmitted through a driving line 217 extending in the low direction. The signal PCLKB_IN is input into the buffer circuit 218 and an output signal from the buffer circuit 218 is transmitted through a driving line 216. The signal output from the buffer circuit 218 is input into the buffer circuit 219 and the signal PCLKB is output from the buffer circuit 219. The signal PCLKB is input into the charge circuit 202 in the signal processor 103. Specifically, the signal PCLKB is input into the gate of the PMOS transistor composing the charge circuit 202.

Referring to FIG. 6A, one driving line 216 is provided for the signal processors 103 of two lines. An output signal from the buffer circuit 219 is branched at a first branch point 610 and one driving line (a first driving line) resulting from the branching is input into the signal processor 103 of the n-th line (the signal processor of a first pixel). The first branch point 610 is arranged in an area overlapped with the photoelectric conversion area in a plan view. The other driving line (a second driving line) resulting from the branching at the first branch point 610 is input into the signal processor 103 of the n+1-th line (the signal processor of a second pixel). In other words, the signal processors 103 of two lines and two columns share the output signal from the buffer circuit 219. Although provision of one driving line 216 for the signal processors 103 of one line is supposed, the provision of the buffer circuits 218 and 219 to improve the reliability of the pulse signals increases the number of the buffer circuits in the entire photoelectric conversion apparatus. Since the buffer circuits 218 and 219 are provided on the same semiconductor layer as that of the circuits composing the signal processors 103, the increase in the number of the buffer circuits 218 and 219 limits the number of the circuits composing the signal processors. In contrast, the provision of one driving line for the signal processors arranged in the multiple lines has the advantage of ensuring the degree of freedom of the circuits composing the signal processors even if the buffer circuits are arranged.

Referring to FIG. 6A, the pulse signal transmitted through the driving line 216 extending in the line direction is input into the signal processors 103 of two lines and two columns through the driving line 216. Specifically, the output signal from the buffer circuit 219 is branched at a second branch point 620 and one driving line (a third driving line) resulting from the branching is input into the signal processor 103 of the n-th line and the m-th column (the signal processor of the first pixel). The second branch point 620 is arranged in an area overlapped with the photoelectric conversion area in a plan view. The other driving line (a fourth driving line) resulting from the branching at the second branch point 620 is input into the signal processor 103 of the n-th line and the m+1-th column (the signal processor of a third pixel). Sharing a driving signal between the multiple columns enables the number of the buffer circuits 219 to be suppressed and has the advantage of ensuring the degree of freedom of the circuits composing the signal processors.

FIG. 6B illustrates one example of provision of each driving line 216 for the signal processors 103 of four lines. As in the example in FIG. 6B, one driving line 216 may be provided for the signal processors 103 of lines of a number that is greater than or equal to two. Specifically, one driving line 216 is provided for the signal processors 103 of four lines in FIG. 6B. In addition, a branch point for sharing the driving signal is provided for the signal processors 103 of two columns. Furthermore, a layout is adopted in which the driving line 216 is arranged between a block (a first block) of the signal processor 103 of two lines and two columns and a block (a second block) of the signal processors 103 of other two lines and other two columns.

The driving line through which the signal pRES is transmitted and the driving line through which the signal pSEL is transmitted also extend in the line direction although not illustrated in FIG. 6A and FIG. 6B. Each of the driving lines is arranged for the signal processors 103 of each line. For example, like the driving lines 116 illustrated in FIG. 3, the driving line through which the signal pRES is transmitted and the driving line through which the signal pSEL is transmitted are arranged.

As described in detail in the following embodiments, the signal pRES is a signal used to reset the count value. The signal pSEL is a signal for reading out the count value. Since these signals are input into the signal processors 103 once for each frame, these signals are permitted even without high reliability as the signals. Accordingly, since it is not necessary to actively arrange the buffer circuits for the respective driving lines for these signals and the degree of freedom of the circuits composing the signal processors is not restricted by the buffer circuits, the driving lines corresponding to the respective driving signals are provided for the signal processors arranged in the respective lines.

As described above, according to the first embodiment, since the provision of the buffer circuits on the driving lines improves the reliability of the pulse signals, it is possible to provide the photoelectric conversion apparatus capable of suppressing the missing of the counting of the photons. In addition, since the driving lines of a number smaller than the number of the multiple lines are provided for the signal processors arranged in the multiple lines even with the buffer circuits, it is possible to provide the photoelectric conversion apparatus ensuring the degree of freedom of the circuits composing the signal processors.

### Other Examples

Although the lamination structure in which the two semiconductor layers are laminated is described above, a lamination structure in which three semiconductor layers are laminated may be adopted. In this case, the photoelectric conversion elements 102 each including the APD 201 in FIG. 4 may be provided on a first semiconductor layer, the signal processor 103 in FIG. 4 may be provided on a second semiconductor layer, and another signal processor that processes the output signal from the signal processor 103 in FIG. 4 may be provided on a third semiconductor layer. Alternatively, part of the signal processor 103 in FIG. 4 may be provided on the second semiconductor layer, and part of the signal processor 103 in FIG. 4 and another signal processor that processes the output signal from the signal processor 103 may be provided on the third semiconductor layer. Although the semiconductor layers are laminated via the respective wiring layers, face-to-face bonding or face-to-back bonding may be adopted.

### Second Embodiment

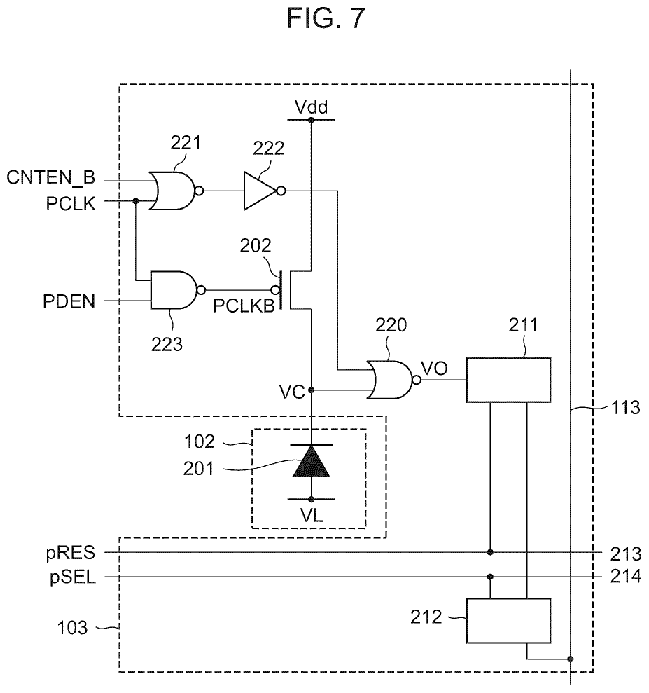

FIG. 7 illustrates a pixel circuit according to a second embodiment. The pixel circuit in FIG. 7 differs from the pixel circuit of the first embodiment in FIG. 4 in that an NOR circuit (a logic circuit) is provided as a waveform shaping circuit, instead of the inverter circuit. In addition, the pixel circuit in FIG. 7 differs from the pixel circuit in FIG. 4 in that the clock signal to be input into the gate of the PMOS transistor composing the charge circuit 202 is input into the waveform shaping circuit through multiple circuits.

### Pixel Circuit

Referring to FIG. 7, a signal PCLK and a signal CNTEN_B are input into a NOR circuit 221 (a logic circuit). The signal PCLK is the clock signal and the signal CNTEN_B is a signal for controlling start or stop of counting. An output signal from the NOR circuit 221 is input into an inverter circuit 222.

The signal PCLK and a signal PDEN are input into a NAND circuit 223 (a logic circuit). The signal PDEN is a signal for controlling start or stop of the operation of the APD 201. An output from the NAND circuit 223 is input into the gate of the PMOS transistor composing the charge circuit 202.

An output signal from the inverter circuit 222 and the output signal from the APD 201 are input into a NOR circuit 220 (a logic circuit).

In this specification, the signal PCLK, the output signal from the inverter circuit 222, and an output signal from the NAND circuit 223 may be referred to as signals corresponding to the input signal into the charge circuit 202 or may be simply referred to as the clock signals. In other words, the signal (the clock signal) corresponding to the input signal into the charge circuit 202 and control signals are capable of being input into the NOR circuit 221 (the logic circuit) and the NAND circuit 223 (the logic circuit). The signal (the clock signal) corresponding to the input signal into the charge circuit 202 and the output signal from the APD 201 are capable of being input into the NOR circuit 220 (the logic circuit).

### Timing Chart

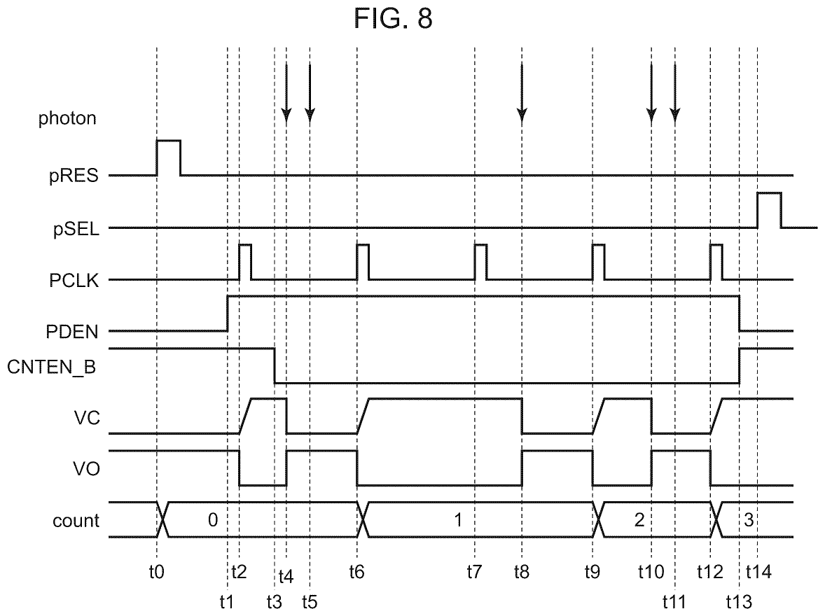

FIG. 8 is a timing chart for describing how the pixel circuit in FIG. 7 is driven.

At a time t0, the signal pRES is varied from the L level to the H level to rest the counter circuit 211. As a result, the count value held in the counter circuit 211 is set to zero.

At a time t1, the signal PDEN is varied from the L level to the H level, and the signal corresponding to the signal PCLK, which is the clock signal, is capable of being output from the NAND circuit 223. In other words, in the state in which the signal PDEN is kept at the L level, the output from the NAND circuit 223 is kept at the H level, and the charge circuit 202 is in the off state regardless of whether the signal PCLK is kept at the L level or in the H level. In contrast, when the signal PDEN is in the H level, the signal PCLKB corresponding to the signal PCLK is input into the charge circuit 202.

At a time t2, the signal PCLK is varied from the L level to the H level and, immediately after that, is varied from the H level to the L level. When the signal PCLK is in the H level, the signal PCLKB, which is the output from the NAND circuit 223, is in the L level and the voltage at the cathode terminal VC is charged from the L level to the H level.

At a time t3, when the signal CNTEN_B is varied from the H level to the L level, the output from the NOR circuit 221 is varied from the L level to the H level and the output from the inverter circuit 222 is varied from the H level to the L level. As a result, since one input signal into the NOR circuit 220 is in the L level, the output from the NOR circuit 220 is varied in response to the variation of the other input signal into the NOR circuit 220. In other words, the output from the NOR circuit 220 is varied in response to the variation of the voltage at the cathode terminal VC. In contrast, when the signal CNTEN_B is kept at the H level, the output from the NOR circuit 221 is kept at the L level and the output from the inverter circuit 222 is kept at the H level. Since one input into the NOR circuit 220 is in the H level, the output signal from the NOR circuit 220 is not varied even if the other input signal into the NOR circuit 220 is varied. In other words, the signal CNTEN_B is a signal for determining whether the output from the cathode terminal VC is input into the counter circuit 211.

At a time t4, upon incidence of the photon, the voltage at the cathode terminal VC is varied from the H level to the L level, and the output from the NOR circuit 220 is varied from the L level to the H level.

At a time t5, since the reverse bias of an extent at which the avalanche multiplication is caused is not applied to the APD 201 although the photon is incident, the voltage at the cathode terminal VC is kept at the L level.

At a time t6, when the signal PCLK is varied from the L level to the H level, the charge circuit 202 is in the on state and the voltage at the cathode terminal VC is varied from the L level to the H level. Since the output from the inverter circuit 222 is varied from the L level to the H level, the signal VO, which is the output from the NOR circuit 220, is varied from the H level to the L level. The counter circuit 211 performs counting at the falling timing of the signal VO.

The NOR circuit 220 composes the logic circuit so that the level of the signal VO is varied in response to the variation of the level of the signal PCLK when the signal PCLK and the voltage at the cathode terminal VC are the input signals into the NOR circuit 220 and the voltage at the cathode terminal VC is in the L level. This is because one count is made without fail if the time period during which the photon is incident exists. For example, a waveform shaping circuit that varies the signal VO from the H level to the L level in response to the variation of the voltage at the cathode terminal VC from the L level to the H level may be adopted. For example, the waveform shaper 210 using the inverter illustrated in FIG. 4 may be adopted. However, if the photon is incident at the timing when the voltage at the cathode terminal VC is varied from the L level to the H level, the voltage at the cathode terminal VC is varied to the L level to keep the L level. As a result, the signal VO is kept at the H level, and the counter circuit 211 is not capable of making one count. Accordingly, when the voltage at the cathode terminal VC is in the L level, the level of the signal VO is enforcedly varied from the H level to the L level in response to the variation of the level of the signal PCLK. This enables the level of the signal VO to be varied without fail, and the counter circuit 211 is capable of making one count without fail.

At a time t7, since the photon is not incident during a time period from the time t6 to the time t7 although the signal PCLK is varied from the L level to the H level, the voltage at the cathode terminal VC is kept at the H level.

At a time t8, upon incidence of the photon, the voltage at the cathode terminal VC is varied from the H level to the L level, and the output from the NOR circuit 220 is varied from the L level to the H level.

At a time t9, when the signal PCLK is varied from the L level to the H level, the voltage at the cathode terminal VC is charged from the L level to the H level. In contrast, the signal VO, which is the output from the NOR circuit 220, is varied from the H level to the L level, and the counter circuit 211 performs counting at the falling timing of the signal VO.

At a time t10, upon incidence of the photon, the voltage at the cathode terminal VC is varied from the H level to the L level and the output from the NOR circuit 220 is varied from the L level to the H level.

At a time t11, since the reverse bias of an extent at which the avalanche multiplication is caused is not applied to the APD 201 although the photon is incident, the voltage at the cathode terminal VC is kept at the L level.

At a time t12, when the signal PCLK is varied from the L level to the H level, the voltage at the cathode terminal VC is charged from the L level to the H level. The signal VO, which is the output from the NOR circuit 220, is varied from the H level to the L level, and the counter circuit 211 performs counting at the falling timing of the signal VO.

At a time t13, the signal PDEN is varied from the H level to the L level, and the pixel circuit is in a state in which the signal corresponding to the signal PCLK is not output from the NAND circuit 223. In other words, in the state in which the signal PDEN is kept at the L level, the output from the NAND circuit 223 is kept at the H level and the charge circuit 202 is kept at the off state regardless of whether the signal PCLK is kept at the L level or the H level.

In addition, at the time t13, the signal CNTEN_B is varied from the L level to the H level, the output from the NOR circuit 221 is varied from the H level to the L level, and the output from the inverter circuit 222 is varied from the L level to the H level. Accordingly, since one input into the NOR circuit 220 is in the H level, the signal VO, which is the output from the NOR circuit 220, is kept at the L level. Consequently, the counter circuit 211 does not count the output signal even if the avalanche multiplication occurs in response to incidence of the photon after the time t13.

At a time t14, upon rising of the signal pSEL, the count value is read out from the counter circuit 211 to the signal line 113 through the selection circuit 212.

### Relationship Between Signal Processors and Driving Lines

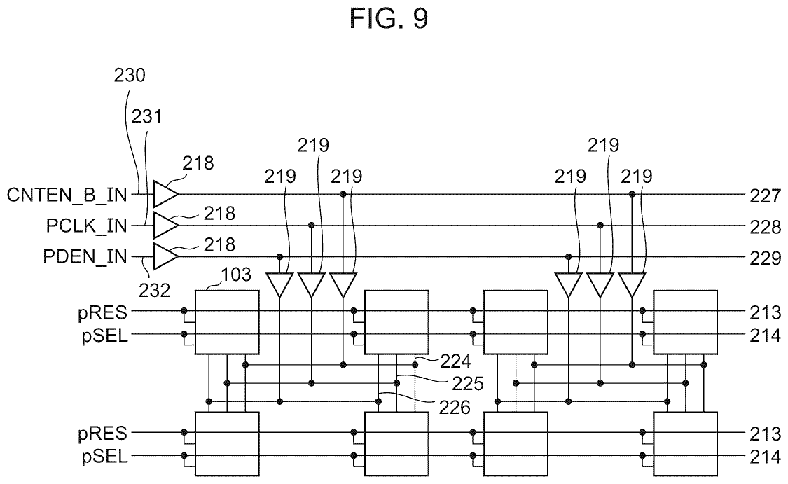

FIG. 9 illustrates the relationship between the driving lines input into the pixel circuit in FIG. 7. Specifically, the relationship between the signal processors 103, the driving lines 213 and 214, driving lines 224 to 232, and the buffer circuits 218 and 219 is illustrated in FIG. 9.

A signal PCLK_IN corresponding to the signal PCLK is a pulse signal output from the vertical scanning circuit unit 110 and is transmitted through the driving line 231. The signal PCLK_IN is input into the buffer circuit 218 and the output signal from the buffer circuit 218 is transmitted through the driving line 228. The signal output from the buffer circuit 218 is input into the NOR circuit 221 and the NAND circuit 223 in the signal processor 103 through the buffer circuit 219 and the driving line 225 as the signal PCLK. The signal PCLKB output from the NAND circuit 223 is input into the charge circuit 202. The signal PCLKB described in the first embodiment differs from the signal PCLK described in the second embodiment only in that the H level and the L level of the waveform of the clock signal are inverted. Accordingly, in this specification, the signal PCLKB and the signal PCLK may be collectively described as the signal corresponding to the input signal into the charge circuit or may be simply described as the clock signal.

The signal CNTEN_B is a signal for controlling start or stop of the counting. A signal CNTEN_B_IN corresponding to the signal CNTEN_B is a pulse signal output from the vertical scanning circuit unit 110 and is transmitted through the driving line 230. The signal CNTEN_B_IN is input into the buffer circuit 218, and the output signal from the buffer circuit 218 is transmitted through the driving line 227. The signal output from the buffer circuit 218 is input into the NOR circuit 221 in the signal processor 103 through the buffer circuit 219 and the driving line 224 as the signal CNTEN_B.

The signal PDEN is a signal for controlling start or stop of the operation of the APD 201. A signal PDEN_IN corresponding to the signal PDEN is a pulse signal output from the vertical scanning circuit unit 110 and is transmitted through the driving line 232. The signal PDEN_IN is input into the buffer circuit 218 and the output signal from the buffer circuit 218 is transmitted through the driving line 229. The signal output from the buffer circuit 218 is input into the NAND circuit 223 in the signal processor 103 through the buffer circuit 219 and the driving line 226 as the signal PDEN.

As described above, if the pulse width of the signal PCLKB input into the charge circuit is narrowed, the charge circuit may have insufficient time to recharge the cathode terminal VC. If the charge circuit has the insufficient recharge time, the photon is not capable of being detected even if the signal PCLKB is input, which may possibly cause the count of the photons to be missed. Accordingly, the signal is transmitted through the buffer circuits 218 and 219 in order to improve the reliability of the signal PCLK corresponding to the signal PCLKB.

One driving line 228 is provided for the signal processors 103 of two lines in FIG. 9. The output signal from the buffer circuit 219 is branched at the first branch point to be input into the signal processors 103 of the n-th line and the signal processors 103 of the n+1-th line. Although provision of one driving line 228 for the signal processors of one line is supposed, the number of the buffer circuits 218 and 219 is increased. Since the buffer circuits 218 and 219 are provided on the same semiconductor layer as that of the circuits composing the signal processors, the increase in the number of the buffer circuits 218 and 219 limits the number of the circuits composing the signal processors. For example, it is not possible to arrange the NOR circuit 220 in the signal processor 103 to disable high functionality.

In contrast, the provision of one driving line for the signal processors of the multiple lines has the advantage of ensuring the degree of freedom of the circuits composing the signal processors even if the buffer circuits are arranged.

In addition, it is necessary to improve the reliability of the signals taking logic with the signal PCLK and the signal corresponding to the signal PCLK. For example, the NAND circuit 223 is configured so as to receive the signal PCLK and the signal PDEN and to output the signal PCLKB. Even when the reliability of the signal PCLK is high, the reliability of the signal PCLKB is reduced if the reliability of the signal PDEN is low. Similarly, the low reliability of the signal CNTEN_B reduces the reliability of the signal input into the NOR circuit 220 to reduce the reliability of the signal that is output from the NOR circuit 220 and is input into the counter circuit 211. As a result, the reliability of the count value is also reduced. Accordingly, it is necessary to provide the buffer circuits for the driving lines through which the signal PDEN and the signal CNTEN_B are transmitted to improve the reliability of the signals. However, the provision of the driving line thorough which the signal PDEN is transmitted and the buffer circuit for the signal processors of one line limits the number of the circuits composing the signal processors. Similarly, the provision of the driving line thorough which the signal CNTEN_B is transmitted and the buffer circuit for the signal processors of one line limits the number of the circuits composing the signal processors.

In order to resolve the above problem, the driving lines 227 and 229 are provided for the signal processors 103 of two lines in the second embodiment, as illustrated in FIG. 9. Specifically, the output signal from the buffer circuit 219 is branched to be input into the signal processors 103 of the n-th line and the signal processors 103 of the n+1-th line through the driving lines 224 and 226. The provision of the corresponding driving lines for the respective signals in the signal processors of the multiple lines has the advantage of ensuring the degree of freedom of the circuits composing the signal processors even if the buffer circuits are arranged.

Referring to FIG. 9, the signal pRES is input into the signal processors 103 through the driving line 213. The signal pSEL is input into the signal processors 103 through the driving line 214. As illustrated in FIG. 8, the signal pRES is a signal for resetting the count value and the signal pSEL is a signal for reading out the count value. These signals are input into the signal processors 103 once for each frame. Accordingly, these signals are permitted even without high reliability as the signals. Accordingly, the buffer circuits are not necessarily arranged on the driving lines 213 and 214 through which the signal pRES and the signal pSEL are supplied to the signal processors 103. Consequently, both of the driving lines 213 and 214 are provided for the signal processors 103 of the n-th line, and both of the driving lines 213 and 214 are provided for the signal processors 103 of the n+1-th line in FIG. 9. In other words, the driving lines corresponding to the respective signals are provided for the signal processors of the respective lines. Even with such a configuration, since it is not necessary to actively arrange the buffer circuits for the respective driving lines, the degree of freedom of the circuits composing the signal processors is not restricted.

As described above, according to the second embodiment, since the provision of the buffer circuits on the driving lines improves the reliability of the pulse signals, it is possible to provide the photoelectric conversion apparatus capable of suppressing the missing of the counting of the photons. In addition, since the driving lines of a number smaller than the number of the multiple lines are provided for the signal processors arranged in the multiple lines even with the buffer circuits, it is possible to provide the photoelectric conversion apparatus ensuring the degree of freedom of the circuits composing the signal processors.

### Other Examples

Although the example in which the NOR circuits and the NAND circuit are used as the logic circuits is described above, any logic circuit may be used as long as the idea of the second embodiment is carried out.

### Third Embodiment

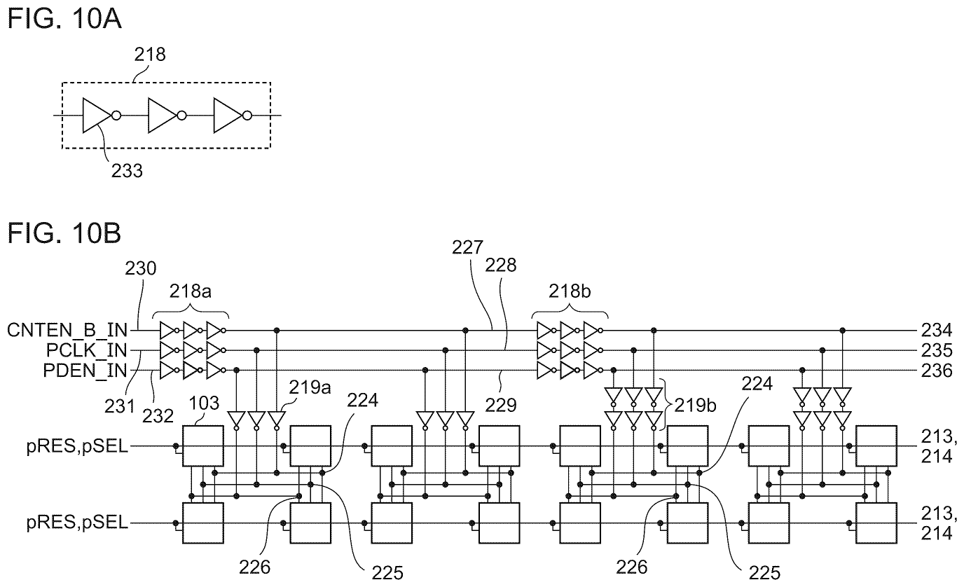

FIG. 10A and FIG. 10B illustrate the buffer circuit and the relationship between the driving lines input into the signal processors in a third embodiment. FIG. 10A illustrates a specific configuration of, for example, the buffer circuit 218 of the first embodiment in FIG. 6A and FIG. 6B and the buffer circuit 218 of the second embodiment in FIG. 9. As illustrated in FIG. 10A, the buffer circuit 218 is composed of, for example, multiple inverter circuits 233. Specifically, three (which is an odd number) inverter circuits 233 are provided in the buffer circuit 218. Since the inverter circuits of odd-number stages are provided in the buffer circuit 218, the input signal into the buffer circuit 218 is inverted from the output signal from the buffer circuit 218. Transmission of the signal while inverting the signal enables variation in the pulse width of the signal to be suppressed. In other words, for example, when the buffer circuit 218 is composed of the inverter circuits of two stages, the pulse width of the signal to be transmitted is greatly varied due to the difference between the rising time and the falling time of the signal pulse if the driving line has high load (resistance or capacitance). In contrast, when the buffer circuit 218 is composed of the inverter circuits of, for example, three stages, since the difference between the rising time and the falling time is offset, it is possible to suppress the variation in the pulse width of the signal to be transmitted to transmit the high-quality signal.

FIG. 10B illustrates the relationship between the signal processors and the driving lines input into the signal processors. FIG. 10B differs from FIG. 9 in that the buffer circuits are illustrated in detail. The relationship between the driving lines input into the signal processors of two lines and four columns is illustrated in FIG. 9, while the relationship between the driving lines input into the signal processors of two lines and eight columns is illustrated in FIG. 10B. In addition, the driving lines for the signal pSEL and the signal pRES are collectively illustrated for convenience in FIG. 10B.

Referring to FIG. 10B, the signals transmitted through driving lines 234, 235, and 236 extending in the line direction are output from a buffer circuit 218a composed of the inverter circuits of three stages and are input into the signal processors 103 through buffer circuits 219a. Since the output signal from the buffer circuit 218a is inverted from the input signal into the buffer circuit 218a, the buffer circuits 219a are each composed of the inverter circuits of odd-number stages. For example, the buffer circuit 219a is composed of the inverter circuits of one stage. The output signals from the buffer circuits 219a are input into the signal processors 103 of two lines and two columns, which compose a first block, and the signal processors 103 of two lines and two columns, which compose a second block.

A buffer circuit 218b is composed of the inverter circuits of three stages. Since the buffer circuit 218a outputs the signal inverted from the input signal and the buffer circuit 218b also outputs the signal inverted from the input signal, the input signal into the buffer circuit 218a corresponds to the output signal from the buffer circuit 218b, and the output signal from the buffer circuit 218b is not inverted. Accordingly, buffer circuit 219b are each composed of the inverter circuits of even-number stages. For example, the buffer circuit 219b is composed of the inverter circuits of two stages. The output signals from the buffer circuits 219b are input into the signal processors 103 of two lines and two columns, which compose a third block, and the signal processors 103 of two lines and two columns, which compose a fourth block.

As described above, according to the third embodiment, since the provision of the buffer circuits on the driving lines improves the reliability of the pulse signals, it is possible to provide the photoelectric conversion apparatus capable of suppressing the missing of the counting of the photons. In addition, since the driving lines of a number smaller than the number of the multiple lines are provided for the signal processors arranged in the multiple lines even with the buffer circuits, it is possible to provide the photoelectric conversion apparatus ensuring the degree of freedom of the circuits composing the signal processors. Furthermore, since the specific configuration of the buffer circuits is devised, it is possible to provide the photoelectric conversion apparatus having the further improved reliability of the pulse signals.

### Fourth Embodiment

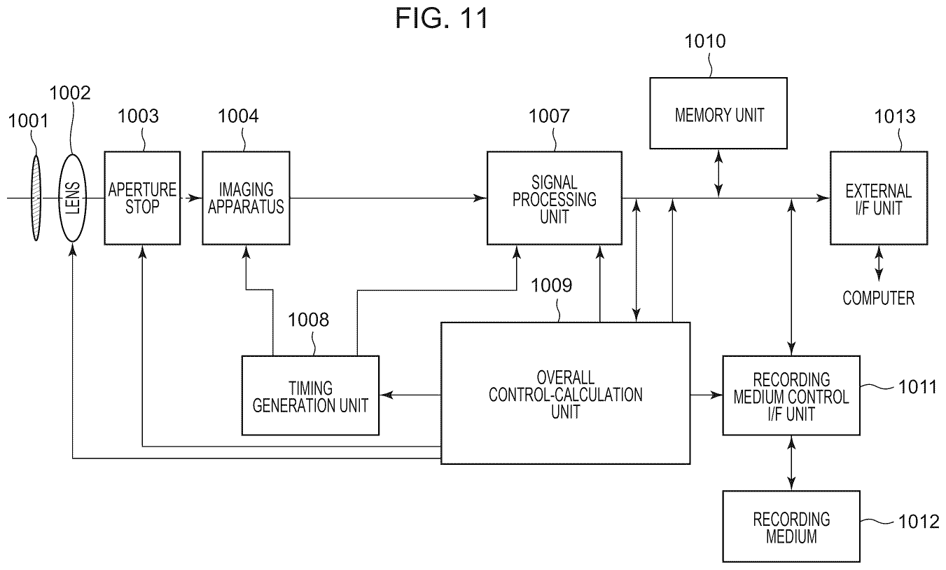

A photoelectric conversion system according to a fourth embodiment will now be described with reference to FIG. 11. FIG. 11 is a block diagram illustrating a schematic configuration of the photoelectric conversion system according to the fourth embodiment.

The photoelectric conversion apparatuses described in the above embodiments are applicable to various photoelectric conversion systems. The photoelectric conversion systems to which the photoelectric conversion apparatuses are applicable include, for example, a digital still camera, a digital camcorder, a monitoring camera, a copier, a facsimile, a mobile phone, an on-vehicle camera, and an observation satellite.

A camera module including an optical system, such as a lens, and an imaging apparatus is also included in the photoelectric conversion system. The block diagram of a digital still camera is illustrated as an example in FIG. 11.

The photoelectric conversion system illustrated in FIG. 11 includes an imaging apparatus 1004, which is an example of the photoelectric conversion apparatus, and a lens 1002 that forms an optical image of an object on the imaging apparatus 1004. The photoelectric conversion system also includes an aperture stop 1003 for varying the amount of light passing through the lens 1002 and a barrier 1001 for protecting the lens 1002. The lens 1002 and the aperture stop 1003 compose an optical system that focuses light on the imaging apparatus 1004. The imaging apparatus 1004 is the photoelectric conversion apparatus of any of the above embodiments and converts the optical image formed by the lens 1002 into an electric signal.

The photoelectric conversion system further includes a signal processing unit 1007, which is an image generator that processes an output signal from the imaging apparatus 1004 to generate an image. The signal processing unit 1007 performs an operation to output image data through a variety of correction and compression, if needed. The signal processing unit 1007 may be formed on the semiconductor layer on which the imaging apparatus 1004 is provided or may be formed on another semiconductor layer different from that of the imaging apparatus 1004. The imaging apparatus 1004 and the signal processing unit 1007 may be formed on the same semiconductor layer.

The photoelectric conversion system further includes a memory unit 1010 for temporarily storing the image data and an external interface unit (external I/F unit) 1013 for communicating with an external computer or the like. The photoelectric conversion system further includes a recording medium 1012, such as a semiconductor memory, on which imaging data is recorded or from which the imaging data is read out and a recording medium control interface unit (recording medium control I/F unit) 1011 for performing recording on or readout from the recording medium 1012. The recording medium 1012 may be incorporated in the photoelectric conversion system or may be detachable.

The photoelectric conversion system further includes an overall control-calculation unit 1009 that controls various arithmetic operations and the entire digital still camera and a timing generation unit 1008 that outputs various timing signals to the imaging apparatus 1004 and the signal processing unit 1007. The timing signals and so on may be input from the outside of the photoelectric conversion system. It is sufficient for the photoelectric conversion system to include at least the imaging apparatus 1004 and the signal processing unit 1007, which processes the output signal from the imaging apparatus 1004.

The imaging apparatus 1004 outputs an imaging signal to the signal processing unit 1007. The signal processing unit 1007 performs certain signal processing to the imaging signal output from the imaging apparatus 1004 to output the image data. The signal processing unit 1007 generates an image using the imaging signal.

As described above, according to the fourth embodiment, it is possible to realize the photoelectric conversion system to which the photoelectric conversion apparatus (the imaging apparatus) of any of the above embodiments is applied.

### Fifth Embodiment

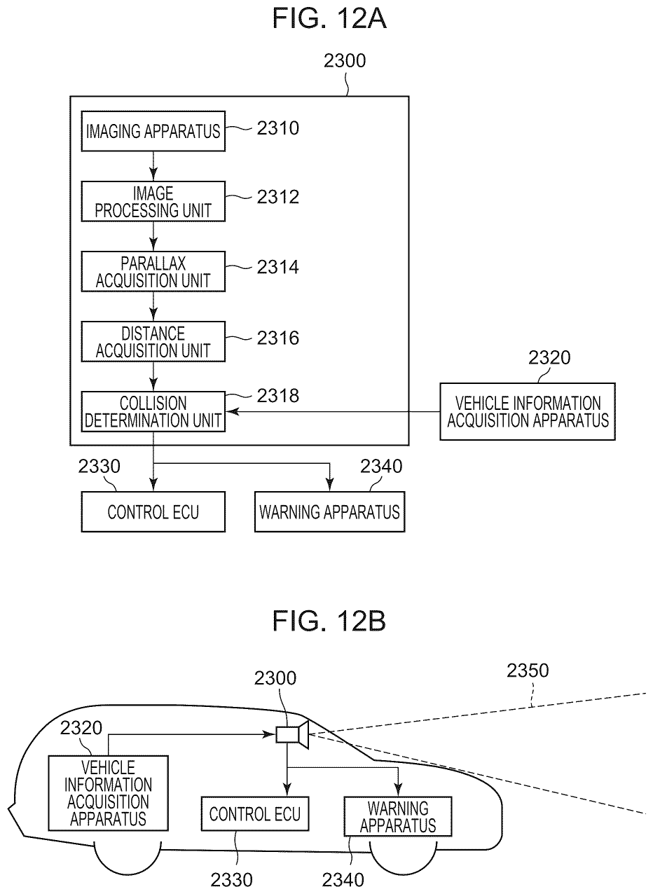

A photoelectric conversion system and a movable body according to a fifth embodiment will now be described with reference to FIG. 12A and FIG. 12B. FIG. 12A and FIG. 12B are diagrams illustrating the configurations of the photoelectric conversion system and the movable body, respectively, of the fifth embodiment.

FIG. 12A illustrates an example of the photoelectric conversion system concerning an on-vehicle camera. A photoelectric conversion system 2300 includes an imaging apparatus 2310. The imaging apparatus 2310 is the photoelectric conversion apparatus described in any of the above embodiments. The photoelectric conversion system 2300 also includes an image processing unit 2312 that performs image processing to multiple pieces of image data acquired by the imaging apparatus 2310. The photoelectric conversion system 2300 further include a parallax acquisition unit 2314 that calculates a parallax (a phase difference of a parallax image) from the multiple pieces of image data acquired by the photoelectric conversion system 2300. The photoelectric conversion system 2300 further includes a distance acquisition unit 2316 that calculates the distance to a target object based on the calculated parallax and a collision determination unit 2318 that determines whether the possibility of collision exists based on the calculated distance. Here, the parallax acquisition unit 2314 and the distance acquisition unit 2316 are examples of a distance information acquisition unit that acquires distance information to the target object. In other words, the distance information is information concerning the parallax, the amount of defocusing, the distance to the target object, and so on. The collision determination unit 2318 may determine the possibility of collision using any distance information. The distance information acquisition unit may be realized by hardware that is dedicatedly designed or may be realized by a software module. Also, the distance information acquisition unit may be realized by a field programmable gate array (FPGA), an application specific integrated circuit (ASIC), or the like or may be realized by any combination of these.

The photoelectric conversion system 2300 is connected to a vehicle information acquisition apparatus 2320 and is capable of acquiring vehicle information, such as a vehicle speed, a yaw rate, and a rudder angle. In addition, the photoelectric conversion system 2300 is connected to a control electronic control unit (ECU) 2330, which is a control apparatus (a control unit) that outputs a control signal causing a vehicle to generate braking force based on the result of determination in the collision determination unit 2318. Furthermore, the photoelectric conversion system 2300 is connected to a warning apparatus 2340 that issues a warning to a driver based on the result of determination in the collision determination unit 2318. For example, when the possibility of collision is high as the result of determination in the collision determination unit 2318, the control ECU 2330 performs vehicle control to avoid collision and/or reduce damage by, for example, braking, easing an accelerator, or suppressing engine output.

The warning apparatus 2340 issues a warning to a user by, for example, giving a warning, such as sound; displaying warning information on a screen of a car navigation system or the like; and imparting motion to a seat belt or a steering wheel.

In the fifth embodiment, an image of the circumference of the vehicle, for example, the front side or the rear side of the vehicle, is captured by the photoelectric conversion system 2300. FIG. 12B illustrates the photoelectric conversion system 2300 when an image of the front of the vehicle is captured (an imaging range 2350). The vehicle information acquisition apparatus 2320 issues an instruction to the photoelectric conversion system 2300 or the imaging apparatus 2310. With such a configuration, it is possible to further improve the accuracy of the ranging.

Although the example of the control to avoid the collision with another vehicle is described above, the photoelectric conversion system is applicable to control of an automatic operation while following another vehicle, control of an automatic operation so as to stay in its lane, and so on. In addition, the photoelectric conversion system is not limited to the vehicle, such as a host vehicle, and is applicable to a movable body (a movable system), such as a ship or a vessel, an aircraft, or an industrial robot. Furthermore, the photoelectric conversion system is not limited to the movable body and is applicable to a device, such as an intelligent transport system (ITS), which widely uses object recognition.

### Sixth Embodiment

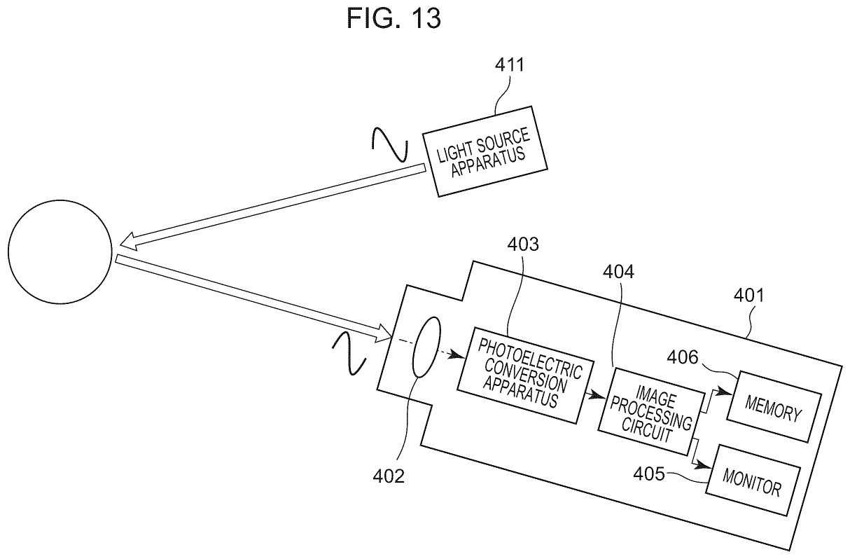

A photoelectric conversion system of a sixth embodiment will now be described with reference to FIG. 13. FIG. 13 is a block diagram illustrating an example of the configuration of a distance image sensor, which is the photoelectric conversion system.

Referring to FIG. 13, a distance image sensor 401 includes an optical system 402, a photoelectric conversion apparatus 403, an image processing circuit 404, a monitor 405, and a memory 406. The distance image sensor 401 is capable of receiving light (modulated light or pulsed light) that is flooded from a light source apparatus 411 to an object and that is reflected from the surface of the object to acquire a distance image in accordance with the distance to the object.

The optical system 402 is composed of one lens or multiple lenses. The optical system 402 leads image light (incident light) from the object to the photoelectric conversion apparatus 403 to form an image on a light receiving surface (a sensor portion) of the photoelectric conversion apparatus 403.

The photoelectric conversion apparatus described in any of the above embodiments is applied as the photoelectric conversion apparatus 403. A distance signal indicating the distance calculated from a light receiving signal output from the photoelectric conversion apparatus 403 is supplied to the image processing circuit 404.

The image processing circuit 404 performs the image processing to build the distance image based on the distance signal supplied from the photoelectric conversion apparatus 403. The distance image (image data) acquired through the image processing is supplied to the monitor 405 for display and/or is supplied to the memory 406 for storage (recording).

With the distance image sensor 401 configured in the above manner, it is possible to acquire, for example, the more accurate distance image with improvement of the features of the pixels by applying the photoelectric conversion apparatus described above.

### Seventh Embodiment

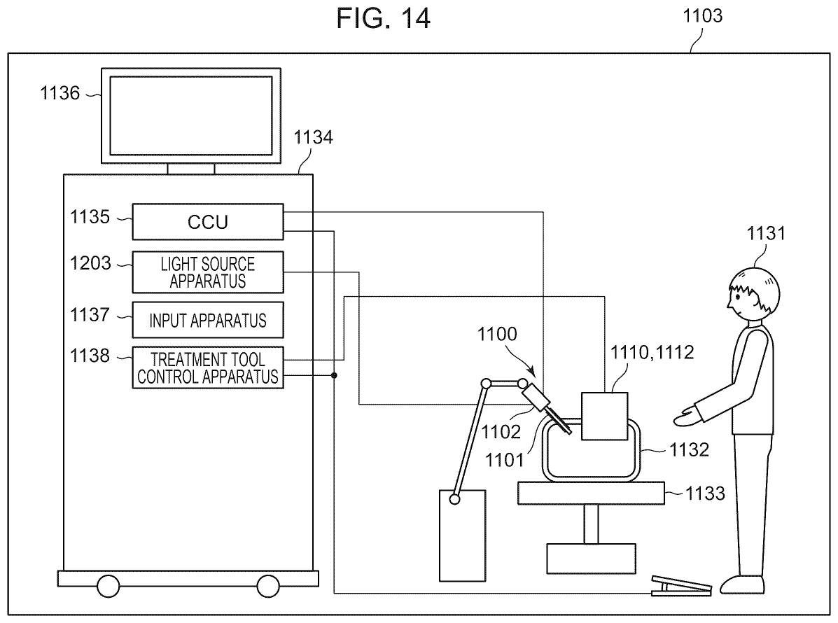

A photoelectric conversion system of a seventh embodiment will now be described with reference to FIG. 14. FIG. 14 illustrates an example of a schematic configuration of an endoscopic surgery system, which is the photoelectric conversion system of the seventh embodiment.

A state is illustrated in FIG. 14, in which an operator (doctor) 1131 is doing surgery to a patient 1132 on a patient bed 1133 using an endoscopic surgery system 1103. As illustrated in FIG. 14, the endoscopic surgery system 1103 is composed of an endoscope 1100, a surgical tool 1110, and a cart 1134 on which various devices for the endoscopic surgery are mounted.

The endoscope 1100 is composed of a lens tube 1101 and a camera head 1102 connected to the base end of the lens tube 1101. An area of a predetermined length from the tip of the lens tube 1101 is inserted into the body cavity of the patient 1132. Although the endoscope 1100 composed as a so-called hard mirror having the hard lens tube 1101 is illustrated in the example in FIG. 14, the endoscope 1100 may be composed as a so-called soft mirror having the soft lens tube.

An opening having a set-in objective lens is provided at the tip of the lens tube 1101. A light source apparatus 1203 is connected to the endoscope 1100. Light generated by the light source apparatus 1203 is led to the tip of the lens tube 1101 by a light guide extending in the lens tube 1101 and is radiated to an observation target in the body cavity of the patient 1132 via the objective lens. The endoscope 1100 may be a forward-viewing endoscope or may be an oblique-viewing endoscope or a side-viewing endoscope.

An optical system and a photoelectric conversion apparatus are provided in the camera head 1102, and reflected light (observed light) from the observation target is focused on the photoelectric conversion apparatus by the optical system. The observed light is subjected to the photoelectric conversion by the photoelectric conversion apparatus to generate an electric signal corresponding to the observed light, that is, an image signal corresponding to an observed image. The photoelectric conversion apparatus described above in any of the above embodiments is capable of being used as the photoelectric conversion apparatus here. The image signal is transmitted to a camera control unit (CCU) 1135 as raw data.

The CCU 1135 is composed of a central processing unit (CPU), a graphics processing unit (GPU), or the like and controls the operations of the endoscope 1100 and a display apparatus 1136 in a centralized manner. In addition, the CCU 1135 receives the image signal from the camera head 1102 to perform a variety of image processing, such as development (mosaic processing), for displaying an image corresponding to the image signal to the image signal.

The display apparatus 1136 displays an image corresponding to the image signal subjected to the image processing in the CCU 1135 under the control of the CCU 1135.

The light source apparatus 1203 is composed of a light source, such as a light emitting diode (LED), and supplies irradiation light, in irradiating a surgical site or the like, to the endoscope 1100.

An input apparatus 1137 is an input interface for the endoscopic surgery system 1103. A user can input a variety of information and various instructions into the endoscopic surgery system 1103 with the input apparatus 1137.

A treatment tool control apparatus 1138 controls driving of an energy treatment tool 1112 for cauterization of tissue, dissection, sealing of blood vessel, and so on.

The light source apparatus 1203, which supplies the irradiation light in irradiating of the surgical site to the endoscope 1100, may be composed of a white light source composed of, for example, the LED, a laser light source, or a combination of these. Since the output strength and the output timing of each color (each wavelength) are capable of being controlled with high accuracy when the white light source is composed of a combination of RGB laser light sources, it is possible to perform adjustment of a white balance of a captured image in the light source apparatus 1203. In addition, in this case, the image corresponding to each of RGB is capable of being captured in time division by radiating laser light from each of the RGB laser light sources to the observation target in time division and controlling driving of an imaging element of the camera head 1102 in synchronization with the radiation timing. With this method, it is possible to acquire a color image without providing a color filter in the imaging element.

In addition, driving of the light source apparatus 1203 may be controlled so that the intensity of the light to be output is changed for every predetermined time. It is possible to generate an image of a high dynamic range without so-called under exposure and over exposure by controlling the driving of the imaging element of the camera head 1102 in synchronization with the timing of change of the intensity of the light to acquire the images in time division and combining the images.

Furthermore, the light source apparatus 1203 may be configured so as to be capable of supplying the light of a predetermined wavelength band corresponding to special-light observation. In the special-light observation, for example, the wavelength dependence of absorption of light in body tissue is used. Specifically, the light of a band narrower than that of the irradiation light (that is, white light) in normal observation is radiated to shoot certain tissue, such as a blood vessel of a superficial layer of a mucous membrane, with high contrast.

Also, in the special-light observation, fluorescence observation may be performed in which an image is acquired with fluorescence occurring in response to radiation of excitation light. Radiating the excitation light to the body tissue to observe the fluorescence from the body tissue, locally injecting reagent, such as indocyanine green (ICG), into the body tissue and radiating the excitation light corresponding to the wavelength of the fluorescence of the reagent to the body tissue to generate a fluorescent image, or the like, is capable of being performed in the fluorescence observation. The light source apparatus 1203 may be configured so as to be capable of supplying the narrow-band light or the excitation light supporting the special-light observation.

### Eighth Embodiment

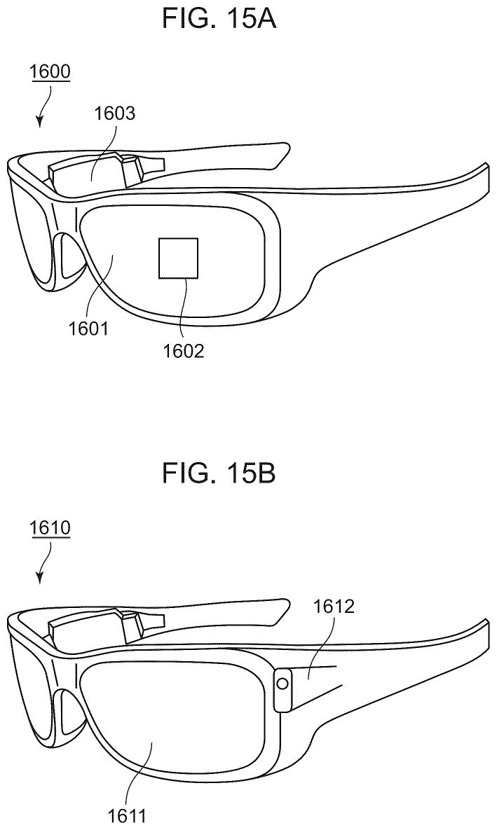

A photoelectric conversion system of an eighth embodiment will now be described with reference to FIG. 15A and FIG. 15B. FIG. 15A illustrates an example of the configuration of eyeglasses 1600 (smart glasses), which are the photoelectric conversion system.

The eyeglasses 1600 include a photoelectric conversion apparatus 1602. The photoelectric conversion apparatus 1602 is the photoelectric conversion apparatus described in any of the first to third embodiments. A display apparatus including a light emitting unit, such as an organic LED (OLED) or an LED, may be provided at the rear face side of a lens 1601. One photoelectric conversion apparatus 1602 may be provided or multiple photoelectric conversion apparatuses 1602 may be provided. Also, the photoelectric conversion apparatuses of multiple kinds may be combined for usage. The arrangement position of the photoelectric conversion apparatus 1602 is not limited to the one in FIG. 15A.

The eyeglasses 1600 further include a control apparatus 1603. The control apparatus 1603 functions as a power supply that supplies electric power to the photoelectric conversion apparatus 1602 and the display apparatus described above. In addition, the control apparatus 1603 controls the operations of the photoelectric conversion apparatus 1602 and the display apparatus. An optical system to focus light on the photoelectric conversion apparatus 1602 is formed in the lens 1601.

FIG. 15B is used to describe eyeglasses 1610 (smart glasses) according to one example of an application. The eyeglasses 1610 include a control apparatus 1612. A photoelectric conversion apparatus corresponding to the photoelectric conversion apparatus 1602 and a display apparatus are mounted in the control apparatus 1612. An optical system to project light emitted from the photoelectric conversion apparatus and the display apparatus in the control apparatus 1612 is formed in a lens 1611, and an image is projected on the lens 1611. The control apparatus 1612 functions as a power supply to supply electric power to the photoelectric conversion apparatus and the display apparatus and controls the operations of the photoelectric conversion apparatus and the display apparatus. The control apparatus may include a line-of-sight detector that detects the line of sight of a wearer. Infrared rays may be used for the detection of the line of sight. An infrared light emitter emits infrared light to the eyeball of a user who gazes on a displayed image. Reflected light of the emitted infrared light from the eyeball is detected by an imager including a light-receiving element to acquire the captured image of the eyeball. A reduction unit to reduce the light from the infrared light emitter to the display unit in a plan view is provided to reduce decrease in the image quality.

The line of sight of the user to the displayed image is detected from the captured image of the eyeball acquired through the shooting with the infrared light. An arbitrary known method is applicable for the detection of the line of sight using the captured image of the eyeball. For example, a line-of-sight detecting method based on a Purkinje image generated by reflection of the irradiation light from the cornea may be used.

More specifically, the line-of-sight detection based on a pupil-cornea reflection method is performed. A light-of-sight vector representing the orientation of the eyeball (rotation angle) is calculated based on the image of the pupil included in the captured image of the eyeball and the Purkinje image using the pupil-cornea reflection method to detect the line of sight of the user.

The display apparatus of the eighth embodiment may include the photoelectric conversion apparatus including the light-receiving element and may control the image displayed in the display apparatus based on line-of-sight information about the user from the photoelectric conversion apparatus.

Specifically, the display apparatus determines a first field-of-view area on which the user gazes and a second field-of-view area other than the first field-of-view area based on the line-of-sight information. The first field-of-view area and the second field-of-view area may be determined by a controller of the display apparatus or may be received from an external controller that determines the first field-of-view area and the second field-of-view area. In a display area of the display apparatus, the display resolution of the first field-of-view area may be controlled so as to be higher than the display resolution of the second field-of-view area. In other words, the resolution of the second field-of-view area may be made lower than that of the first field-of-view area.

The display area includes a first display area and a second display area different from the first display area. An area having higher priority may be determined from the first display area and the second display area based on the line-of-sight information. The first display area and the second display area may be determined by the controller of the display apparatus or may be received from an external controller that determines the first display area and the second display area. The resolution of the area having higher priority may be controlled so as to be higher than the resolution of the area other than the area having higher priority. In other words, the resolution of the area having relatively low priority may be made low.

Artificial intelligence (AI) may be used for the determination of the first field-of-view area and the area having higher priority. The AI may be a model in which the angle of the line of sight and the distance to a target object ahead of the line of sight are estimated from the image of the eyeball using the image of the eyeball and the direction to which the eyeball in the image actually directed as teacher data. An AI program may be held in the display apparatus, the photoelectric conversion apparatus, or an external apparatus. When an external apparatus holds the AI program, the AI program is transferred to the display apparatus via communication.

In display control based on visual contact detection, smart glasses further including a photoelectric conversion apparatus that captures an external image are applicable. The smart glasses are capable of displaying external information that is captured in real time.

The embodiments described above may be appropriately varied without departing from the technical idea of the present disclosure. Examples in which the configuration of part of any embodiment is added to another embodiment or is replaced with the configuration of part of another embodiment are also included in the embodiments of the present disclosure.

Although the driving lines extending in the line direction are described in the embodiments described above, the lines may be replaced with the columns. For example, in case of a photoelectric conversion apparatus including the driving lines extending in the column direction, since rotation of the photoelectric conversion apparatus makes the driving lines extending in the line direction, it is possible to represent the driving lines as the ones extending in the line direction. Similarly, for example, a first pixel arranged in a first column is synonymous with a first pixel arranged in a first line and a second pixel arranged in a second column is synonymous with a second pixel arranged in a second line.

While the present disclosure has described exemplary embodiments, it is to be understood that some embodiments are not limited to the disclosed exemplary embodiments. The scope of the following claims is to be accorded the broadest interpretation so as to encompass all such modifications and equivalent structures and functions.

This application claims priority to Japanese Patent Application No. 2024-050583, which was filed on Mar. 26, 2024 and which is hereby incorporated by reference herein in its entirety.

What is claimed is:

1. A photoelectric conversion apparatus comprising:
a plurality of pixels arranged in a matrix,
wherein each of the pixels includes at least
a photodiode configured to perform avalanche multiplication, and
a signal processing circuit configured to process an output signal from the photodiode,
wherein the signal processing circuit includes
a charge circuit arranged between the photodiode and a power supply and configured to apply voltage to the photodiode, and
a counter circuit configured to count the output signal from the photodiode, the photoelectric conversion apparatus further comprising:
a driving line through which a signal to be input into the signal processing circuit is transmitted,
wherein the driving line is branched into at least a first driving line and a second driving line via a buffer circuit,
wherein a signal from the first driving line is capable of being input into the signal processing circuit of a first pixel, of the plurality of pixels, on a first line, and
wherein a signal from the second driving line is capable of being input into the signal processing circuit of a second pixel, of the plurality of pixels, on a second line different from the first line.

2. The photoelectric conversion apparatus according to claim 1,
wherein a signal corresponding to an input signal into the charge circuit is transmitted through the driving line.

3. The photoelectric conversion apparatus according to claim 2, further comprising:
a logic circuit into which the signal corresponding to the input signal into the charge circuit and a control signal are capable of being input.

4. The photoelectric conversion apparatus according to claim 3,
wherein the control signal is a signal for controlling start or stop of an operation of the photodiode.

5. The photoelectric conversion apparatus according to claim 3,
wherein the control signal is a signal for controlling start or stop of counting in the counter circuit.

6. The photoelectric conversion apparatus according to claim 3,
wherein the driving line through which the control signal is transmitted is branched into at least a third driving line and a fourth driving line via a buffer circuit,
wherein a signal from the third driving line is capable of being input into the signal processing circuit of the first pixel, and
wherein a signal from the fourth driving line is capable of being input into the signal processing circuit of the second pixel.

7. The photoelectric conversion apparatus according to claim 1,
wherein the signal processing circuit includes a logic circuit provided between the photodiode and the counter circuit, and
wherein a signal corresponding to an input signal into the charge circuit and the output signal from the photodiode are capable of being input into the logic circuit.

8. The photoelectric conversion apparatus according to claim 7,
wherein an output signal from a logic circuit into which the signal corresponding to the input signal into the charge circuit and a control signal are capable of being input is capable of being input into the logic circuit provided between the photodiode and the counter circuit.

9. The photoelectric conversion apparatus according to claim 1,
wherein the signal processing circuit includes a selection circuit configured to select readout of a signal from the counter circuit, and
wherein the driving line through which a signal input into the selection circuit is transmitted includes a driving line provided for the selection circuit of the first pixel and a driving line provided for the selection circuit of the second pixel.

10. The photoelectric conversion apparatus according to claim 1,
wherein the driving line through which a signal for resetting a count value of the counter circuit is transmitted includes a driving line provided for the counter circuit of the first pixel and a driving line provided for the counter circuit of the second pixel.

11. The photoelectric conversion apparatus according to claim 1,
wherein the driving line is branched into the first driving line and the second driving line at a first branch point,
wherein the driving line is branched into at least a third driving line and a fourth driving line at a second branch point different from the first branch point,
wherein a signal from the third driving line is capable of being input into the signal processing circuit of the first pixel on a first column, and
wherein a signal from the fourth driving line is capable of being input into the signal processing circuit of a third pixel on a second column different from the first column.

12. The photoelectric conversion apparatus according to claim 11, further comprising:
a photoelectric conversion area in which the plurality of pixels is arranged,
wherein the first branch point and the second branch point are arranged in an area overlapped with the photoelectric conversion area in a plan view.

13. The photoelectric conversion apparatus according to claim 1,
wherein the buffer circuit includes a plurality of inverter circuits.

14. The photoelectric conversion apparatus according to claim 13,
wherein the buffer circuit includes an odd number of the inverter circuits.

15. A photoelectric conversion system comprising:
the photoelectric conversion apparatus according to claim 1; and
a signal processing unit configured to generate an image using a signal output from the photoelectric conversion apparatus.

16. A movable body comprising:
the photoelectric conversion apparatus according to claim 1; and
a control unit configured to control movement of the movable body using a signal output from the photoelectric conversion apparatus.
